(19) United States
(12) Patent Application Publication
(10) Pub. No.: US 2022/0277902 A1
(43) Pub. Date: Sep. 1, 2022

(54) DICHALCOGENIDE COMPOSITE ELECTRODE AND SOLAR CELL AND USES

(71) Applicant: The Board of Regents of the University of Oklahoma, Norman, OK (US)

(72) Inventors: Zhisheng Shi, Norman, OK (US); Jijun Qiu, Norman, OK (US)

(21) Appl. No.: 17/631,229

(22) PCT Filed: Jul. 29, 2020
(86) PCT No.: PCT/US20/44039

§ 371 Date: Jan. 28, 2022

Related U.S. Application Data
(60) Provisional application No. 62/880,989, filed on Jul. 31, 2019.

(51) Int. Cl. H01G 9/20; H01L 51/42; H01L 51/44

(52) U.S. Cl. CPC H01G 9/2054; H01L 51/4206; H01L 51/442; H01G 9/2009

(57) ABSTRACT

A solar cell having a transparent conducting layer disposed upon a substrate, an electron transporting layer (ETL) disposed upon the transparent conducting layer, a perovskite layer disposed upon the ETL layer, an inorganic dichalcogenide material disposed upon the perovskite layer, and a conducting material disposed upon the dichalcogenide material, the dichalcogenide material and the conducting material together comprising a dichalcogenide composite electrode. In another embodiment, the solar cell has a first conducting material disposed upon a substrate, an inorganic dichalcogenide material disposed upon the first conducting material forming a dichalcogenide composite electrode, a perovskite layer disposed upon the dichalcogenide composite electrode, an ETL disposed upon the perovskite layer, and a second conducting material disposed upon the ETL.

### CROSS REFERENCE TO RELATED APPLICATIONS

The present patent application claims priority under 37 CFR § 119(e) to U.S. Provisional Patent Application Ser. No. 62/880,989, filed on Jul. 31, 2019, the entire contents of which are hereby expressly incorporated herein by reference.

### BACKGROUND

Organic or inorganic (A) metal (M) halide (X) perovskites (AMX₃) have set off a new research boom in the field of photovoltaics. Within a decade, the highest certified efficiency of organic-inorganic hybrid perovskite solar cells has exceeded 23%, which is approaching to commercial crystalline silicon solar cells. The success of such AMX₃ semiconductor devices is attributed to their intrinsic properties. The high photoelectric conversion efficiency and the relatively simple and inexpensive preparation process offer a very attractive potential for commercialization. However, the commercialization of current AMX₃-based solar cell technologies is still facing substantial roadblocks related predominately to long-term material and device instability under working conditions.

The instability of the solar cells comes mostly from the degradation of the organic-inorganic perovskite absorber materials and organic charge-transport materials in the devices. The instability of the simple perovskite materials involves hygroscopic nature-induced moisture instability, high chemical activity-induced UV instability, volatile induced-thermal instability and structural instability due to unsuitable effective tolerance factors. For these reasons, many different technologies have been developed to improve the stability of the perovskites as well as to further improve their performance. These technologies include elemental composition engineering, 2D perovskite structure designing, all-inorganic perovskite structure, inorganic carrier transport materials, electrode material preparation, and the encapsulation method.

An important aspect of high-performance perovskite solar cells (PSCs) concerns the nature of the organic electron transporting material/layer (ETM/ETL) and hole transporting material/layer (HTM/HTL), which are configured in either a normal structure (FIG. 1(a)) or an inverted structure (FIG. 1(b)). The substrate typically includes a Transparent Conductive Oxide (TCO) such as fluorine-doped tin oxide (FTO) or indium-doped tin oxide (ITO) on glass. Incident light is on the substrate side. In the conventional structures, TiO₂ is normally used as the ETM/ETL and an organic HTM/HTL is coated on the perovskite absorber. The roles of the ETM/ETL and HTM/HTL are: (1) to reduce the photo-generated carrier recombination at the electrodes and thus enhance the power conversion efficiency (PCE), (2) to serve as a protection layer to prevent the top metal electrode from corrosion when in contact with iodides, and (3) to block inward diffusion of gas/moisture and the outward diffusion of iodine-containing volatile species. Organic HTMs (o-HTMs) such as spiro-MeOTAD, poly(triarylamine) (PTAA), and poly(3,4-ethylenedioxythiophene) (PEDOT), however, suffer from poor long-term UV and thermal stability. They are also very expensive, which questions the validity of suggestions that these perovskite solar cell architectures are a low-cost solution for next generation solar cells. To overcome this problem, various inorganic HTMs (i-HTMs) have been developed. To ensure high material quality, however, these i-HTMs need to be fabricated at high temperatures, which significantly deteriorates the quality of the perovskite materials. Therefore, the i-HTM is typically used in the inverted structures (see FIG. 1(b)). Unfortunately, an upper organic-ETL (o-ETL) is still needed, which introduces similar problems as the o-HTM. In one approach to address this problem, carbon-based electrodes (FIG. 2) can be processed at lower temperatures, and therefore normal structures could be used to eliminate the issues with the o-HTM. However, the poor quality of the contact at the perovskite/carbon interface causes the PCE of this kind of PSC to be low in comparison with o-HTM-based PSCs.

In addition to the stability issues, the electrode must also serve to prevent moisture penetration into the perovskite film layer. Silver (Ag) or gold (Au) is usually employed as the top electrode in a PSC. However, Ag reacts with halide to form silver halides in the electrode, and Au can also diffuse into the perovskites causing irreversible device degradation.

It is to overcoming the various problems and disadvantages listed above that the devices of the present disclosure are directed.

### BRIEF DESCRIPTION OF THE DRAWINGS

FIG. 1(a) is a schematic illustration of a perovskite solar cell structure according to electrode polarity n-i-p normal structure with n-type ETM.

FIG. 1(b) is a schematic illustration of the perovskite solar cell structure according to electrode polarity p-i-n inverted structure with p-type HTM.

FIG. 2 is a schematic diagram showing the energy level of a perovskite solar cell (PSC) using a carbon-based electrode.

FIG. 3A is a schematic of a PSC constructed in accordance with the present disclosure.

FIG. 3B is a schematic diagram showing the energy levels of the PSC of FIG. 3A.

FIG. 4 is a schematic of a generalized embodiment of a perovskite solar cell of the present disclosure.

FIG. 5 is a schematic of a generalized embodiment of an inverted PSC of the present disclosure.

FIG. 6 is a schematic diagram showing the energy levels of the various layers of the PSC of FIG. 4.

FIG. 7 is a schematic of a particular embodiment of a PSC of the present disclosure.

FIG. 8 is a schematic diagram showing the energy levels of the various layers of the PSC of FIG. 7.

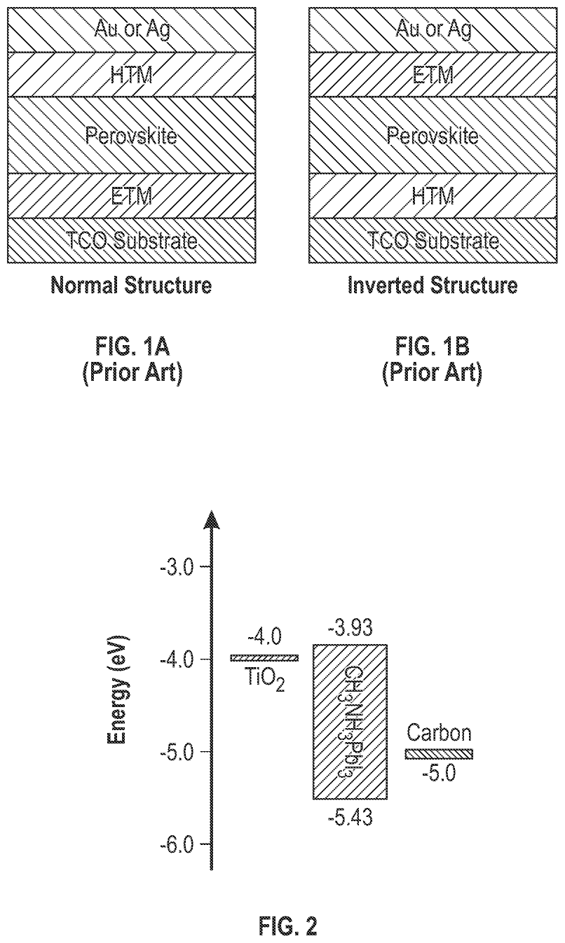

### DETAILED DESCRIPTION

To solve the problems associated with organic ETM/HTM, certain embodiments of the present disclosure are directed to perovskite solar cells which include an inorganic dichalcogenide material (which may be a layered 2D material) in place of the conventional organic carrier transport material used in PSCs. For example, in one non-limiting embodiment, a SnSe₂ layer is used with a conducting material to form a dichalcogenide composite electrode where holes and electrons recombine. This layer also serves as a protective layer. In certain embodiments in which the perovskite layer is inorganic, the dichalcogenide composite electrode is also inorganic, such that the perovskite solar cell is fully inorganic, thereby avoiding instability issues caused by organic materials currently used in many PSCs, and reducing costs, providing a PSC able to work efficiently in an outdoor environment. Alternatively, the perovskite layer may be organic, as explained in further detail below. A plurality of the solar cells of the present disclosure may be organized into a photovoltaic (PV) module, a plurality of which may be arranged into a PV panel. A plurality of such PV panels may be organized into an array. The solar cells and PV modules may be used to generate electrical current.

Before describing various embodiments of the present disclosure in more detail by way of exemplary description, examples, and results, it is to be understood as noted above that the present disclosure is not limited in application to the details of methods and apparatus as set forth in the following description. The present disclosure is capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the present disclosure pertains. All patents, published patent applications, and non-patent publications referenced in any portion of this application, including but not limited to, U.S. Provisional Patent Application Ser. No. 62/880,989, filed on Jul. 31, 2019, are herein expressly incorporated by reference in their entirety to the same extent as if each individual patent or publication was specifically and individually indicated to be incorporated by reference.

As utilized in accordance with the methods and apparatus of the present disclosure, the following terms, unless otherwise indicated, shall be understood to have the following meanings:

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The term “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used herein, all numerical values or ranges (e.g., in units of length such as micrometers or millimeters) include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, of 1-10, 10-20, 20-30, 30-40, 40-50, 50-60, 60-75, 75-100, 100-150, 150-200, 200-250, 250-300, 300-400, 400-500, 500-750, 750-1,000, includes ranges of 1-20, 10-50, 50-100, 100-500, and 500-1,000, for example.

As used herein, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error. Further, in this detailed description, each numerical value (e.g., temperature, time, mass, volume, concentration, etc.) should be read once as modified by the term “about” (unless already expressly so modified), and then read again as not so modified unless otherwise indicated in context. As noted above, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10. Thus, even if specific data points within the range, or even no data points within the range, are explicitly identified or specifically referred to, it is to be understood that any data points within the range are to be considered to have been specified, and that the inventors possessed knowledge of the entire range and the points within the range. Unless otherwise stated, the term “about” or “approximately”, where used herein when referring to a measurable value such as an amount, length, thickness, a temporal duration, and the like, is meant to encompass, for example, variations of ±20% or ±10%, or ±5%, or ±1%, or ±0.1% from the specified value, as such variations are appropriate to perform the disclosed methods and as understood by persons having ordinary skill in the art.

As used herein, the term “substantially” means that the subsequently described parameter, event, or circumstance completely occurs or that the subsequently described parameter, event, or circumstance occurs to a great extent or degree. For example, the term “substantially” means that the subsequently described parameter, event, or circumstance occurs at least 90% of the time, or at least 91%, or at least 92%, or at least 93%, or at least 94%, or at least 95%, or at least 96%, or at least 97%, or at least 98%, or at least 99%, of the time, or means that the dimension or measurement is within at least 90%, or at least 91%, or at least 92%, or at least 93%, or at least 94%, or at least 95%, or at least 96%, or at least 97%, or at least 98%, or at least 99%, of the referenced dimension or measurement (e.g., thickness).

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Turning now to further description of particular embodiments of the present disclosure, provided herein, in certain embodiments the perovskite layers of the presently disclosed devices have the inorganic composition AMX3, wherein A may be one or more monovalent cations, e.g., Li+, Na+, K+, Cs+, Rb+, Ag+, and Cu+, M is one or more divalent cations, such as Cu2+, Ni2+, Co2+, Fe2+, Mn2+, Pd2+, Cd2+, Ge2+, Eu2+, Sn2+, and Pb2+, and X is one or more monovalent anions such as F—, Cl—, Br—, and I—. Examples of the AMX3 composition include, but are not limited to: Quantum Dot-CsPbI3, Cs0.925K0.075PbI2Br, CsPb0.96Bi0.04I3, CsPb0.95Ca0.0513, CsPb0.9Sn0.1IBr2, CsPb0.95Mn0.05I2Br, CsPbIBr2, CsPbI3-xBr2, CsPbI3:Clx, and CsPbI3.

In other embodiments, the perovskite layers of the presently disclosed devices have an organic/inorganic composition AMX3, wherein A may be one or more organic (and optionally inorganic) monovalent cations, e.g., methylammonium (MA), formamidinum (FA), n-butylammonium (BA), 3-(2-pyridyl)-pyrazol-1-yl (PZPY), Li+, Na+, K+, Cs+, Rb+, Ag+, and Cu+; M is one or more divalent cations, such as Cu2+, Ni2+, Co2+, Fe2+, Mn2+, Pd2+, Cd2+, Ge2+, Eu2+, Sn2+, and Pb2+; and X is one or more monovalent anions such as F—, Cl—, Br—, and I—. Non-limiting examples of such organic/inorganic perovskites having the formula AMX3 include MA0.6FA0.4PbI3, Cs0.2FA0.8PbI3, Rb0.05FA0.95PbI3 MAPb(I/Cl)3, MAPbI3-x-yBrxCly, FA0.95MA0.05Pb(I0.95Br0.05)3, Cs0.05(FA0.83MA0.17)0.95Pb(I0.83Br0.17)3, Rb0.05Cs0.05(FA0.83MA0.17)0.90Pb(I0.83Br0.17)3, (CH3(CH2)3NH3)2(MA)n−1PbnI3n+1(n=3,4), BA0.05(FA0.83Cs0.17)0.91Pb(I0.8Br0.2)3, and FAIPbI2-PZPY Cs0.04MA0.16FA0.8PbI0.85Br0.15.

In other non-limiting embodiments, A may be ammonia, methylamine, methanimidamide, aminomethanamidine, formamidine, ethylenediamine, dimethylamine, imidazole, acetamidine, propylamine, isopropylamine, trimethylenediamine, ethylamine, butylamine, isobutylamine, tert-butylamine, diethylamine, 5-aminovaleric acid, thiophenemethylamine, hexylamine, aniline, benzylamine, phenylethylamine, octylamine, decylamine, dodecylamine, tetradecylamine, hexadecylamine, oleylamine, octadecylamine, eicosylamine, Li, Na, K, Rb, Cs, or Cu; M may be Cd, Co, Cr, Cu, Fe, Ge, Pb, or Sn; and X may be Cl, Br, I, cyanide (CN), cyanate (NCO), thiocyanate (NCS), selenocyanate (SeCN), or tellurocyanate (TeCN).

Thus, the perovskite material may be an organic-inorganic hybrid perovskite material formed by an inorganic material and an organic material.

In certain non-limiting embodiments of the present disclosure, the dichalcogenide material has the formula MX2, wherein M is a metal such as Sn, Mo, W, Ti, Ni, Co, Fe, Mn, i.e., a transition metal, and X is a chalcogen (S, Se, and/or Te), and wherein the metal comprises a single layer between two chalcogenide layers. Examples of such dichalcogenide compounds include, but are not limited to SnSe2, SnS2, SnTe2, WS2, WSe2, WTe2, MoS2, MoSe2, and MoTe2. The dichalcogenide material may comprise a 2D layer

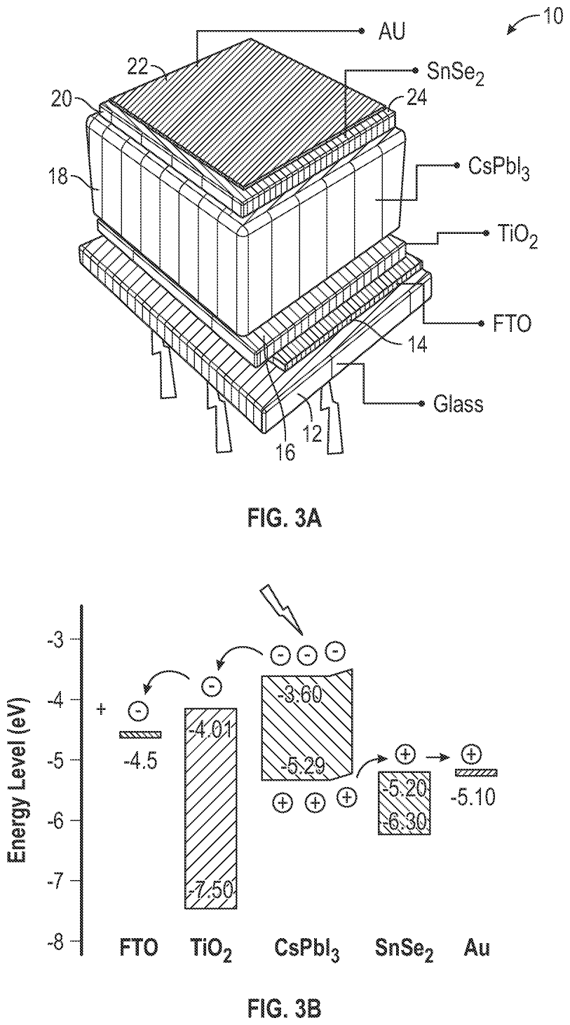

In a non-limiting embodiment of the present disclosure, CsI and PbI2 can be used as source materials for CsPbI3 growth. HxCs1-xI can be synthesized as molecular beam epitaxy (MBE) source material to grow HxCs1-xPbI. HI can be used as an additive material to improve structure stability. Group I elements such as Na and K can be used for PbSe p-type doping. Surface p+ doping can create favorable band bending as shown in FIG. 3B to block electron moving to electrode and thus reduce electron hole recombination at electrode. Other inorganic p-type doping elements can be used.

Cs(SnxPb1-x)I3 can be formed using CsI, SnI2 and PbI2 as source materials for vacuum deposition, enabling tuning of the bandgap energy to between 1.3 eV and 1.7 eV, enabling optimization of bandgap for single junction device or fabrication of tandem structure.

The o-HTM (o-HTL) is eliminated by using a dichalcogenide layer (e.g., SnSe2) together with a conducting material such as a metal (e.g., Ag, Au, Cu, or Pt) or a metal-like material (e.g., graphite), forming a dichalcogenide composite electrode (“composite electrode”). As is shown in FIG. 3B, the electron affinity of SnSe2 is 5.2±0.1 eV, which is very close to the valence band energy (5.29 eV) of CsPbI3, making it an excellent “Ohmic” contact for holes to transport and recombine at the CsPbI3/SnSe2 interface and/or to transport further to the Au contact to recombine with electrons in the Au electrode. With a work function of 5.1 eV, Au forms a good Ohmic contact with SnSe2. In one embodiment, the SnSe2 only needs to be the thinnest possible pin-hole free SnSe2 to serve as a “transport/protection” layer to prevent conductive material, e.g., Au, from diffusion into the perovskite layer. In one embodiment, as noted above, SnSe2/Au is used to form a composite electrode for CsPbI3 perovskite. SnSe2 can be grown on CsPbI3-based perovskites on different substrates produced. TiO2 can be coated on FTO/glass substrate. Subsequently, CsPbI3-based perovskite and a thin layer of SnSe2 is grown on TiO2/FTO/glass to form a solar cell structure represented in FIG. 3A.

As noted above, FIG. 3A illustrates, in one non-limiting embodiment, a perovskite solar cell 10 having a substrate 12 constructed of glass, a transparent conducting layer 14 disposed on the substrate 12 and constructed of fluorine-doped tin oxide (FTO), an electron transport layer 16 disposed on the transparent conducting layer 14 and constructed of Titanium dioxide, a perovskite layer 18 disposed on the electronic transport layer 16, a dichalcogenide layer 20 disposed on the perovskite layer 18, and a conductive layer 22 disposed on the dichalcogenide layer 20. The dichalcogenide layer 20 and the conductive layer 22 form a dichalcogenide composite electrode 24. The dichalcogenide composite electrode 24 is a layered 2D material, which in this example is formed of a layer of dichalcogenide material, e.g., SnSe2 having an electron affinity of 5.2 eV, covered with a layer of conducting material (e.g., Au) comprising a portion of a top composite electrode. The dichalcogenide composite electrode 24 also serves as a protective layer. In this embodiment, the dichalcogenide composite electrode 24 makes the perovskite solar cell fully inorganic thereby avoiding instability issues caused by organic materials currently used in PSCs, and reduces cost. Further, as noted above, and as shown in FIG. 3B, the electron affinity of SnSe2 is 5.2±0.1 eV which is very close to the valence band energy (5.29 eV) of CsPbI3, making it an excellent “Ohmic” contact for holes to transport and recombine at the CsPbI3/SnSe2 interface and/or to transport further to Au contact to recombine with electrons in the Au electrode. With a work function of 5.1 eV, Au forms a good Ohmic contact with SnSe2. A thin pin-hole free SnSe2 layer, i.e., the dichalcogenide layer 20 serves as a “transport/protection” layer to prevent material from the conductive layer 22 (e.g., Au) from diffusion into the perovskite layer 18. Thus, in one non-limiting embodiment, the disclosure is directed to an apparatus including the dichalcogenide composite electrode 24 (e.g., SnSe2/Au) in combination with the perovskite layer 18 such as CsPbI3.

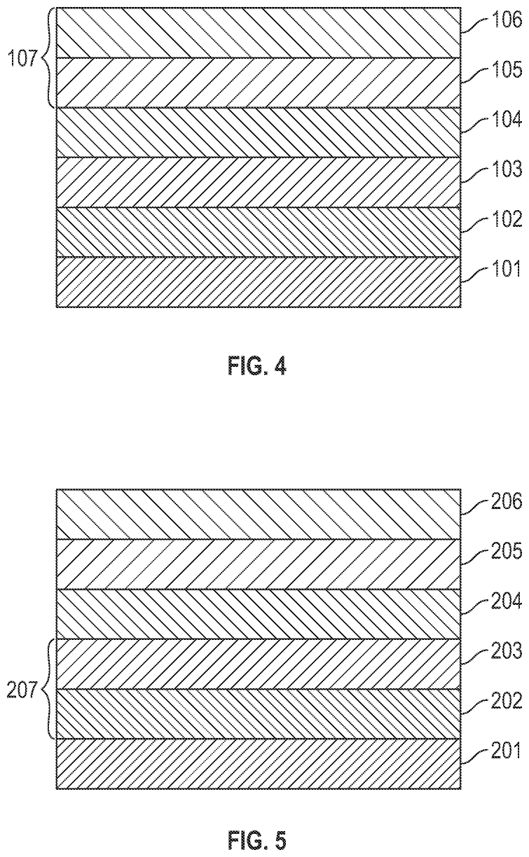

FIG. 4 illustrates a generalized embodiment of the perovskite solar cell 10 (“PSC” 10) of the present disclosure. The PSC 10 of FIG. 4 is constructed with (1) a substrate 101, which may be glass, PET (polyethylene terephthalate), or any substrate conventionally used in solar cells, having a thickness in a range of, for example, about 100 □m to about 5,000 □m, (2) a transparent conducting layer 102 disposed upon the substrate 101, and which may be made, in a non-limiting example, from any type of transparent conductive oxide (TCO) material used conventionally in solar cells, such as metal oxides, doped or undoped, e.g., a fluorine-doped tin oxide (FTO), indium-doped tin oxide (ITO), aluminum-doped ZnO (AZO), or gallium-doped ZnO (GZO), having a thickness in a range of, for example, about 1 □m to about 10 □m, (3) an electron transporting layer (ETL) 103 comprising an electron transporting material, e.g., TiO2, ZnO, SnO2, ZrO2, Al2O3, Cs2CO3, having a thickness in a range of, for example, about 0.01 □m to about 1 □m, (4) a perovskite layer 104 for creating an electron-hole couple such as described above, and having a thickness in a range of, for example, about 0.1 μm to about 1 μm, and (5) a dichalcogenide composite electrode 107 comprising a dichalcogenide material 105 having a thickness in a range of, for example, about 0.005 □m to about 0.5 □m, and a conducting material 106 which may be a metal- or metal-like material, e.g., Au, Ag, Cu, Pt, or graphite, having a thickness in a range of, for example, about 0.1 μm to about 2 μm. The perovskite layer 104 may comprise multi-layer tandem structures.

FIG. 5 illustrates an alternate embodiment of the present disclosure, an inverted PSC. The inverted PSC comprises a substrate 201, comprising a material such as used for the substrate 101 of FIG. 4, which may be glass or any substrate conventionally used in solar cells. Disposed on the substrate 201 is a dichalcogenide composite electrode 207, which comprises a conducting material 202 such as the conducting material 106 of FIG. 4, and an inorganic dichalcogenide material 203, comprising a dichalcogenide material such as the dichalcogenide material 105 of FIG. 4. Disposed on the composite electrode 207 is a perovskite layer 204, comprising a material such as the perovskite layer 104 of FIG. 4. Disposed on the perovskite layer 204 is an electron transporting layer (ETL) 205 comprising an electron transporting material, such as the material used to form the ETL 103 of FIG. 4. Finally, a second conducting material 206 is disposed on the ETL 205.

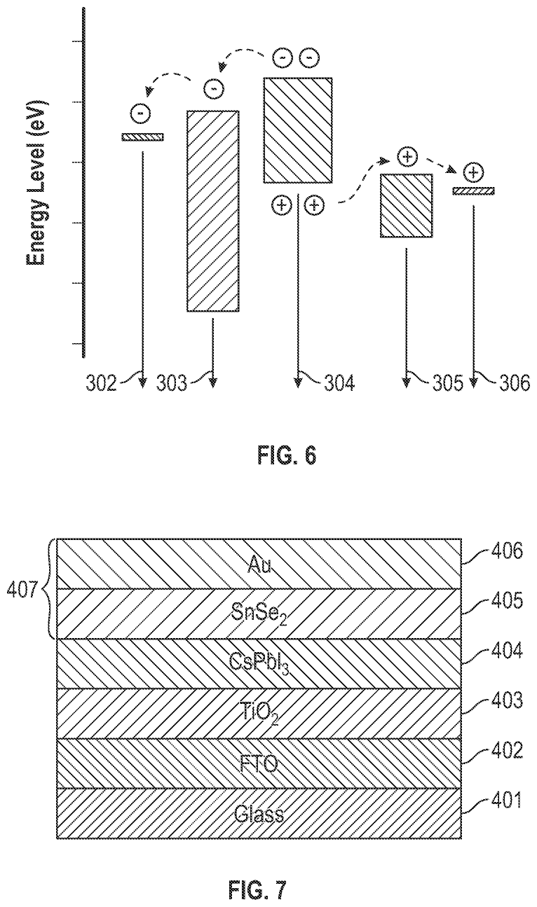

FIG. 6 schematically illustrates the energy levels of the various layers of the PSC of FIG. 4, wherein 302 is the energy level of the TCO layer 102, 303 is the energy level of the ETL layer 103, 304 is the energy level of the perovskite layer 104, 305 is the energy level of the dichalcogenide layer 105, and 306 is the energy level of the conducting material 106.

FIG. 7 illustrates a particular, non-limiting, embodiment of the PSC of the present disclosure. The PSC is constructed with (1) a glass substrate 401, (2) a transparent conductive oxide (TCO) layer 402 disposed upon the substrate 401, comprising fluorine-doped tin oxide (FTO), (3) an electron transporting layer (ETL) 403 comprising TiO2 as an electron transporting material, (4) a perovskite layer 404 comprising CsPbI3, and (5) dichalcogenide composite electrode 407 comprising a dichalcogenide layer 405 comprising SnSe2 and a conducting material 406 comprising gold.

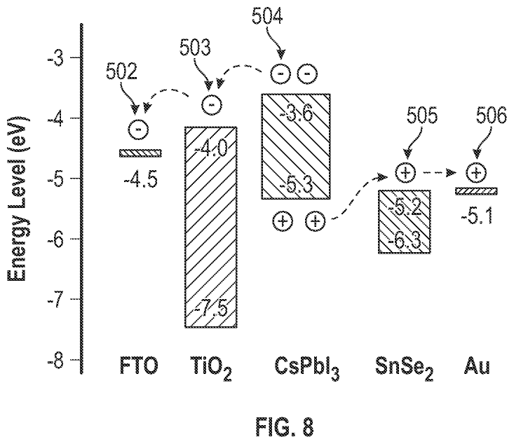

FIG. 8 schematically illustrates the energy levels of the various layers of the PSC of FIG. 7, wherein 502 is the energy level of the FTO layer 402; 503 is the energy level of the TiO2 layer 403; 504 is the energy level of CsPbI3, the perovskite layer 404; 505 is the energy level of SnSe2, the dichalcogenide layer 405; and 506 is the energy level of the gold electrode 406.

The following is a number list of non-limiting illustrative embodiments of the inventive concept disclosed herein:
1. A solar cell comprising:
   a substrate;
   a transparent conducting layer disposed upon the substrate;
   an electron transporting layer (ETL) disposed upon the transparent conducting layer, the ETL comprising an electron transporting material;
   a perovskite layer for creating an electron-hole couple, the perovskite layer disposed upon the ETL layer;
   an inorganic dichalcogenide material disposed upon the perovskite layer; and
   a conducting material disposed upon the dichalcogenide material, wherein the dichalcogenide material and the conducting material together comprise a dichalcogenide composite electrode.
2. The solar cell of illustrative embodiment 1, wherein the dichalcogenide material has the formula MX₂, wherein M is a metal and X is a chalcogen.
3. The solar cell of illustrative embodiment 2, wherein M is a transition metal selected from the group consisting of Sn, Mo, W, Ti, Ni, Co, Fe, and Mn.
4. The solar cell of illustrative embodiment 2, wherein X is selected from the group consisting of S, Se, and Te.
5. The solar cell of illustrative embodiment 2, wherein the dichalcogenide material is selected from the group consisting of SnSe₂, SnS₂, SnTe₂, WS₂, WSe₂, WTe₂, MoS₂, MoSe₂, and MoTe₂.
6. The solar cell of illustrative embodiment 1, wherein the perovskite layer comprises a composition having the formula AMX₃, wherein A is at least one monovalent cation, M is at least one divalent cation, and X is at least one monovalent anion.
7. The solar cell of illustrative embodiment 6, wherein A is selected from the group consisting of Li⁺, Na⁺, K⁺, Cs⁺, Rb⁺, Ag⁺, Cu⁺, methylammonium (MA), formamidinum (FA), n-butylammonium (BA), and 3-(2-pyridyl)-pyrazol-1-yl (PZPY).
8. The solar cell of illustrative embodiment 6, wherein M is selected from the group consisting of Cu²⁺, Ni²⁺, Co²⁺, Fe²⁺, Mn²⁺, Pd²⁺, Cd²⁺, Ge²⁺, Eu²⁺, Sn²⁺, and Pb₂₊.
9. The solar cell of illustrative embodiment 6, wherein X is selected from the group consisting of F⁻, Cl⁻, Br⁻, and I⁻.
10. The solar cell of illustrative embodiment 1, wherein the perovskite layer is inorganic.
11. The solar cell of illustrative embodiment 10, wherein the perovskite layer is selected from the group consisting of Quantum Dot-CsPbI₃, Cs_{0.925}K_{0.075}PbI₂Br, CsPb_{0.96}Bi_{0.04}I₃, CsPb_{0.95}Ca_{0.05}I₃, CsPb_{0.9}Sn_{0.1}IBr₂, CsPb_{0.95}Mn_{0.05}I₂Br, CsPbIBr₂, CsPbI₃₋ₓBrₓ, CsPbI₃:Clₓ, and CsPbI₃.
12. The solar cell of illustrative embodiment 1, wherein the perovskite layer is at least partially organic.
13. The solar cell of illustrative embodiment 12, wherein the perovskite layer is selected from the group consisting of MA_{0.6}FA_{0.4}PbI₃, Cs_{0.2}FA_{0.8}PbI₃, Rb_{0.05}FA_{0.95}PbI₃MAPb(I/Cl)₃, MAPbI_{3-x-y}BrₓCl_{y}, FA_{0.95}MA_{0.05}Pb(I_{0.95}Br_{0.05})₃, Cs_{0.05}(FA_{0.83}MA_{0.17})_{0.95}Pb(I_{0.83}Br_{0.17})₃, Rb_{0.05}Cs_{0.05}(FA_{0.83}MA_{0.17})_{0.90}Pb(I_{0.83}Br_{0.17})₃, (CH₃(CH₂)₃NH₃)₂(MA)ₙ₋₁PbₙI₃ₙ₊₁(n=3,4), BA_{0.05}(FA_{0.83}Cs_{0.17})_{0.91}Pb(I_{0.8}Br_{0.2})₃, and FAIPbI₂—PZPY Cs_{0.04}MA_{0.16}FA_{0.8}PbI_{0.85}Br_{0.15}.
14. The solar cell of illustrative embodiment 1, wherein the transparent conducting layer is fluorine-doped tin oxide (FTO), indium-doped tin oxide (ITO), aluminum-doped ZnO (AZO), or gallium-doped ZnO (GZO).
15. The solar cell of illustrative embodiment 1, wherein the ETL comprises a transition metal oxide.
16. The solar cell of illustrative embodiment 1, wherein the ETL is selected from the group consisting of TiO₂, ZnO, SnO₂, ZrO₂, Al₂O₃, and Cs₂CO₃.
17. The solar cell of illustrative embodiment 1, wherein the conducting material is selected from the group consisting of Au, Ag, Cu, Pt, and graphite.
18. A solar cell comprising:
   a substrate;
   a first conducting material disposed upon the substrate;
   an inorganic dichalcogenide material disposed upon the first conducting material, wherein the dichalcogenide material and the conducting material together comprise a dichalcogenide composite electrode;
   a perovskite layer for creating an electron-hole couple, the perovskite layer disposed upon the dichalcogenide material;
   an electron transporting layer (ETL) disposed upon the perovskite layer, the ETL comprising an electron transporting material; and
   a second conducting material disposed upon the ETL.
19. The solar cell of illustrative embodiment 18, wherein the dichalcogenide material has the formula MX₂, wherein M is a metal and X is a chalcogen.
20. The solar cell of illustrative embodiment 19, wherein M is a transition metal selected from the group consisting of Sn, Mo, W, Ti, Ni, Co, Fe, and Mn.
21. The solar cell of illustrative embodiment 19, wherein X is selected from the group consisting of S, Se, and Te.
22. The solar cell of illustrative embodiment 19, wherein the dichalcogenide material is selected from the group consisting of SnSe₂, SnS₂, SnTe₂, WS₂, WSe₂, WTe₂, MoS₂, MoSe₂, and MoTe₂.
23. The solar cell of illustrative embodiment 18, wherein the perovskite layer comprises a composition having the formula AMX₃, wherein A is at least one monovalent cation, M is at least one divalent cation, and X is at least one monovalent anion.
24. The solar cell of illustrative embodiment 23, wherein A is selected from the group consisting of Li⁺, Na⁺, K⁺, Cs⁺, Rb⁺, Ag⁺, Cu^{t}, methylammonium (MA), formamidinum (FA), n-butylammonium (BA), and 3-(2-pyridyl)-pyrazol-1-yl (PZPY).
25. The solar cell of illustrative embodiment 23, wherein M is selected from the group consisting of Cu²⁺, Ni²⁺, Co²⁺, Fe²⁺, Mn²⁺, Pd²⁺, Cd²⁺, Ge²⁺, Eu²⁺, Sn²⁺, and Pb²⁺.
26. The solar cell of illustrative embodiment 23, wherein X is selected from the group consisting of F⁻, Cl⁻, Br⁻, and I⁻.
27. The solar cell of illustrative embodiment 18, wherein the perovskite layer is inorganic.
28. The solar cell of illustrative embodiment 27, wherein the perovskite layer is selected from the group consisting of Quantum Dot-CsPbI₃, Cs_{0.925}K_{0.075}PbI₂Br, CsPb_{0.96}Bi_{0.04}I₃, CsPb_{0.95}Ca_{0.05}I₃, CsPb_{0.9}Sn_{0.1}IBr₂, CsPb_{0.95}Mn_{0.05}I₂Br, CsPbIBr₂, CsPbI₃₋ₓBrₓ, CsPbI₃:Clₓ, and CsPbI₃.
29. The solar cell of illustrative embodiment 18, wherein the perovskite layer is at least partially organic.
30. The solar cell of illustrative embodiment 29, wherein the perovskite layer is selected from the group consisting of MA_{0.6}FA_{0.4}PbI₃, Cs_{0.2}FA_{0.8}PbI₃, Rb_{0.05}FA_{0.95}PbI₃MAPb(I/Cl)₃, MAPbI_{3-x-y}BrₓCl_{y}, FA_{0.95}MA_{0.05}Pb(I_{0.95}Br_{0.05})₃, Cs_{0.05}(FA_{0.83}MA_{0.17})_{0.95}Pb(I_{0.83}Br_{0.17})₃, Rb_{0.05}Cs_{0.05}(FA_{0.83}MA_{0.17})_{0.90}Pb(I_{0.83}Br_{0.17})₃, (CH₃(CH₂)₃NH₃)₂(MA)ₙ₋₁PbₙI₃ₙ₊₁(n=3,4), BA_{0.05}(FA_{0.83}Cs_{0.17})_{0.91}Pb(I_{0.8}Br_{0.2})₃, and FAIPbI₂—PZPY Cs_{0.04}MA_{0.16}FA_{0.8}PbI_{0.85}Br_{0.15}.
31. The solar cell of illustrative embodiment 18, wherein the ETL comprises a transition metal oxide.
32. The solar cell of illustrative embodiment 18, wherein the ETL is selected from the group consisting of TiO₂, ZnO, SnO₂, ZrO₂, Al₂O₃, and Cs₂CO₃.
33. The solar cell of illustrative embodiment 18, wherein the first conducting material is selected from the group consisting of Au, Ag, Cu, Pt, and graphite.
34. The solar cell of illustrative embodiment 18, wherein the second conducting material is selected from the group consisting of Au, Ag, Cu, Pt, and graphite.
35. A method of producing electricity, comprising exposing the solar cell of illustrative embodiment 1 to sunlight, and collecting the electrical current generated by the solar cell.
36. A method of producing electricity, comprising exposing the solar cell of illustrative embodiment 18 to sunlight, and collecting the electrical current generated by the solar cell.
37. A method of producing electricity, comprising exposing the solar cell of any one of illustrative embodiments 1-34 to sunlight, and collecting the electrical current generated by the solar cell.
38. The solar cell of illustrative embodiment 2 or 3, wherein X is selected from the group consisting of S, Se, and Te.
39. The solar cell of any one of illustrative embodiments 1-3, or 38, wherein the dichalcogenide material is selected from the group consisting of SnSe₂, SnS₂, SnTe₂, WS₂, WSe₂, WTe₂, MoS₂, MoSe₂, and MoTe₂.
40. The solar cell of any one of illustrative embodiments 1-3, 38, or 39, wherein the perovskite layer comprises a composition having the formula AMX₃, wherein A is at least one monovalent cation, M is at least one divalent cation, and X is at least one monovalent anion.
41. The solar cell of illustrative embodiment 40, wherein A is selected from the group consisting of Li⁺, Na⁺, K⁺, Cs⁺, Rb⁺, Ag⁺, Cu⁺, methylammonium (MA), formamidinum (FA), n-butylammonium (BA), and 3-(2-pyridyl)-pyrazol-1-yl (PZPY).
42. The solar cell of illustrative embodiment 40 or 41, wherein M is selected from the group consisting of Cu²⁺, Ni²⁺, Co²⁺, Fe²⁺, Mn²⁺, Pd²⁺, Cd²⁺, Ge²⁺, Eu²⁺, Sn²⁺, and Pb²⁺.
43. The solar cell of any one of illustrative embodiments 40-42, wherein X is selected from the group consisting of F⁻, Cl⁻, Br⁻, and I⁻.
44. The solar cell of any one of illustrative embodiments 1-3 or 38-43, wherein the perovskite layer is inorganic.
45. The solar cell of any one of illustrative embodiments 1-3 or 38-44, wherein the perovskite layer is selected from the group consisting of Quantum Dot-CsPbI₃, Cs_{0.925}K_{0.075}PbI₂Br, CsPb_{0.96}Bi_{0.04}I₃, CsPb_{0.95}Ca_{0.05}I₃, CsPb_{0.9}Sn_{0.1}IBr₂, CsPb_{0.95}Mn_{0.05}I₂Br, CsPbIBr₂, CsPbI₃₋ₓBrₓ, CsPbI₃:Clₓ, and CsPbI₃.
46. The solar cell of any one of illustrative embodiments 1-3 or 38-43, wherein the perovskite layer is at least partially organic.
47. The solar cell of any one of 1-3, 38-43, or 46, wherein the perovskite layer is selected from the group consisting of MA_{0.6}FA_{0.4}PbI₃, Cs_{0.2}FA_{0.8}PbI₃, Rb_{0.05}FA_{0.95}PbI₃MAPb(I/Cl)₃, MAPbI_{3-x-y}BrₓCl_{y}, FA_{0.95}MA_{0.05}Pb(I_{0.95}Br_{0.05})₃, Cs_{0.05}(FA_{0.83}MA_{0.17})_{0.95}Pb(I_{0.83}Br_{0.17})₃, Rb_{0.05}Cs_{0.05}(FA_{0.83}MA_{0.17})_{0.90}Pb(I_{0.83}Br_{0.17})₃, (CH₃(CH₂)₃NH₃)₂(MA)ₙ₋₁PbₙI₃ₙ₊₁(n=3,4), BA_{0.05}(FA_{0.83}Cs_{0.17})_{0.91}Pb(I_{0.8}Br_{0.2})₃, and FAIPbI₂—PZPY Cs_{0.04}MA_{0.16}FA_{0.8}PbI_{0.85}Br_{0.15}.
48. The solar cell of any one of illustrative embodiments 1-3 or 38-47, wherein the transparent conducting layer is fluorine-doped tin oxide (FTO), indium-doped tin oxide (ITO), aluminum-doped ZnO (AZO), or gallium-doped ZnO (GZO).
49. The solar cell of any one of illustrative embodiments 1-3 or 38-48, wherein the ETL comprises a transition metal oxide.
50. The solar cell of any one of illustrative embodiments 1-3 or 38-49, wherein the ETL is selected from the group consisting of TiO₂, ZnO, SnO₂, ZrO₂, Al₂O₃, and Cs₂CO₃.
51. The solar cell of any one of illustrative embodiments 1-3 or 38-50, wherein the conducting material is selected from the group consisting of Au, Ag, Cu, Pt, and graphite.
52. The solar cell of illustrative embodiment 19 or 20, wherein X is selected from the group consisting of S, Se, and Te.
53. The solar cell of any one of illustrative embodiments 18-20 or 52, wherein the dichalcogenide material is selected from the group consisting of SnSe₂, SnS₂, SnTe₂, WS₂, WSe₂, WTe₂, MoS₂, MoSe₂, and MoTe₂.
54. The solar cell of any one of illustrative embodiments 18-20, 52 or 53, wherein the perovskite layer comprises a composition having the formula AMX₃, wherein A is at least one monovalent cation, M is at least one divalent cation, and X is at least one monovalent anion.
55. The solar cell of illustrative embodiment 54, wherein A is selected from the group consisting of Li⁺, Na⁺, K⁺, Cs⁺, Rb⁺, Ag⁺, Cu⁺, methylammonium (MA), formamidinum (FA), n-butylammonium (BA), and 3-(2-pyridyl)-pyrazol-1-yl (PZPY).
56. The solar cell of illustrative embodiment 54 or 55, wherein M is selected from the group consisting of Cu²⁺, Ni²⁺, Co²⁺, Fe²⁺, Mn²⁺, Pd²⁺, Cd²⁺, Ge²⁺, Eu²⁺, Sn²⁺, and Pb²⁺.
57. The solar cell of any one of illustrative embodiments 54-56, wherein X is selected from the group consisting of F⁻, Cl⁻, Br⁻, and I⁻.
58. The solar cell of any one of illustrative embodiments 18-20 or 52-57, wherein the perovskite layer is inorganic.
59. The solar cell of any one of illustrative embodiments 18-20 or 52-58, wherein the perovskite layer is selected from the group consisting of Quantum Dot-CsPbI₃, Cs_{0.925}K_{0.075}PbI₂Br, CsPb_{0.96}Bi_{0.04}I₃, CsPb_{0.95}Ca_{0.05}I₃, CsPb_{0.9}Sn_{0.1}IBr₂, CsPb_{0.95}Mn_{0.05}I₂Br, CsPbIBr₂, CsPbI₃₋ₓBrₓ, CsPbI₃:Clₓ, and CsPbI₃.
60. The solar cell of any one of illustrative embodiments 18-20 or 52-57, wherein the perovskite layer is at least partially organic.
61. The solar cell of any one of illustrative embodiments 18-20, 52-57, or 60, wherein the perovskite layer is selected from the group consisting of MA_{0.6}FA_{0.4}PbI₃, Cs_{0.2}FA_{0.8}PbI₃, Rb_{0.05}FA_{0.95}PbI₃MAPb(I/Cl)₃, MAPbI_{3-x-y}BrₓCl_{y}, FA_{0.95}MA_{0.05}Pb(I_{0.95}Br_{0.05})₃, Cs_{0.05}(FA_{0.83}MA_{0.17})_{0.95}Pb(I_{0.83}Br_{0.17})₃, Rb_{0.05}Cs_{0.05}(FA_{0.83}MA_{0.17})_{0.90}Pb(I_{0.83}Br_{0.17})₃, (CH₃(CH₂)₃NH₃)₂(MA)ₙ₋₁PbₙI₃ₙ₊₁(n=3,4), BA_{0.05}(FA_{0.83}Cs_{0.17})_{0.91}Pb(I_{0.8}Br_{0.2})₃, and FAIPbI₂—PZPY Cs_{0.04}MA_{0.16}FA_{0.8}PbI_{0.85}Br_{0.15}.
62. The solar cell of any one of illustrative embodiments 18-20 or 52-61, wherein the ETL comprises a transition metal oxide.
63. The solar cell of any one of illustrative embodiments 18-20 or 52-62, wherein the ETL is selected from the group consisting of TiO₂, ZnO, SnO₂, ZrO₂, Al₂O₃, and Cs₂CO₃.
64. The solar cell of any one of illustrative embodiments 18-20 or 52-63, wherein the first conducting material is selected from the group consisting of Au, Ag, Cu, Pt, and graphite.
65. The solar cell of any one of illustrative embodiments 18-20 or 52-64, wherein the second conducting material is selected from the group consisting of Au, Ag, Cu, Pt, and graphite.
66. A method of producing electricity, comprising exposing the solar cell of any one of illustrative embodiments 38-65 to sunlight, and collecting the electrical current generated by the solar cell.

While several embodiments have been provided in the present disclosure, it may be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, apparatus and methods described and illustrated in the various embodiments as discrete or separate may be combined or integrated with other systems, components, techniques, or methods without departing from the scope of the present disclosure. Other items shown or discussed as coupled may be directly coupled or may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

1.-66. (canceled)

67. A solar cell comprising:
a substrate;
a transparent conducting layer disposed upon the substrate;
an electron transporting layer (ETL) disposed upon the transparent conducting layer, the ETL comprising an electron transporting material;
a perovskite layer for creating an electron-hole couple, the perovskite layer disposed upon the ETL layer;
an inorganic dichalcogenide material disposed upon the perovskite layer, wherein the dichalcogenide material has the formula MX₂, wherein M is a metal selected from the group consisting of Sn, Mo, and W, and X is a chalcogen selected from the group consisting of S, Se, and Te; and
a conducting material disposed upon the dichalcogenide material, wherein the dichalcogenide material and the conducting material together comprise a dichalcogenide composite electrode.

68. The solar cell of claim 67, wherein the dichalcogenide material is selected from the group consisting of SnSe₂, SnS₂, SnTe₂, WS₂, WSe₂, WTe₂, MoS₂, MoSe₂, and MoTe₂.

69. The solar cell of claim 67, wherein the perovskite layer comprises a composition having the formula AMX₃, wherein A is at least one monovalent cation, M is at least one divalent cation, and X is at least one monovalent anion.

70. The solar cell of claim 69, wherein A is selected from the group consisting of Li⁺, Na⁺, K⁺, Cs⁺, Rb⁺, Ag⁺, Cu⁺, methylammonium (MA), formamidinium (FA), n-butylammonium (BA), and 3-(2-pyridyl)-pyrazol-1-yl (PZPY).

71. The solar cell of claim 69, wherein M of formula AMX₃ is selected from the group consisting of Cu²⁺, Ni²⁺, Co²⁺, Fe²⁺, Mn²⁺, Pd²⁺, Cd²⁺, Ge²⁺, Eu²⁺, Sn²⁺, and Pb²⁺.

72. The solar cell of claim 69, wherein X of formula AMX₃ is selected from the group consisting of F⁻, Cl⁻, Br⁻, and I⁻.

73. The solar cell of claim 67, wherein the perovskite layer is inorganic.

74. The solar cell of claim 73, wherein the perovskite layer is selected from the group consisting of Quantum Dot-CsPbI₃, Cs_{0.925}K_{0.075}PbI₂Br, CsPb_{0.96}Bi_{0.04}I₃, CsPb_{0.95}Ca_{0.05}I₃, CsPb_{0.9}Sn_{0.1}IBr₂, CsPb_{0.95}Mn_{0.05}I₂Br, CsPbIBr₂, CsPbI₃₋ₓBrₓ, CsPbI₃:Clₓ, and CsPbI₃.

75. The solar cell of claim 1, wherein the perovskite layer is at least partially organic.

76. The solar cell of claim 75, wherein the perovskite layer is selected from the group consisting of MA_{0.6}FA_{0.4}PbI₃, Cs_{0.2}FA_{0.8}PbI₃, Rb_{0.05}FA_{0.95}PbI₃MAPb(I/Cl)₃, MAPbI_{3-x-y}BrₓCl_{y}, FA_{0.95}MA_{0.05}Pb(I_{0.95}Br_{0.05})₃, Cs_{0.05}(FA_{0.83}MA_{0.17})_{0.95}Pb(I_{0.83}Br_{0.17})₃, Rb_{0.05}Cs_{0.05}(FA_{0.83}MA_{0.17})_{0.90}Pb(I_{0.83}Br_{0.17})₃, (CH₃(CH₂)₃NH₃)₂(MA)ₙ₋₁PbₙI₃ₙ₊₁(n=3,4), BA_{0.05}(FA_{0.83}Cs_{0.17})_{0.91}Pb(I_{0.8}Br_{0.2})₃, and FAIPbI₂—PZPY Cs_{0.04}MA_{0.16}FA_{0.8}PbI_{0.85}Br_{0.15}.

77. The solar cell of claim 67, wherein the transparent conducting layer is fluorine-doped tin oxide (FTO), indium-doped tin oxide (ITO), aluminum-doped ZnO (AZO), or gallium-doped ZnO (GZO).

78. The solar cell of claim 67, wherein the ETL comprises a transition metal oxide.

79. The solar cell of claim 67, wherein the ETL is selected from the group consisting of TiO₂, ZnO, SnO₂, ZrO₂, Al₂O₃, and Cs₂CO₃.

80. The solar cell of claim 67, wherein the conducting material is selected from the group consisting of Au, Ag, Cu, Pt, and graphite.

81. The solar cell of claim 67, comprising a second conducting material, the second conducting material disposed upon the ETL.

82. The solar cell of claim 81, wherein the second conducting material is selected from the group consisting of Au, Ag, Cu, Pt, and graphite.

83. A method of producing electricity, comprising exposing the solar cell of claim 67 to sunlight, and collecting the electrical current generated by the solar cell.
